(19) United States
(12) Patent Application Publication
(10) Pub. No.: US 2016/0105950 A1
(43) Pub. Date: Apr. 14, 2016

(54) Electronic Device Having Structured Flexible Substrates With Bends

(71) Applicant: Apple Inc., Cupertino, CA (US)

(72) Inventors: Paul S. Drzaic, Morgan Hill, CA (US); Zhen Zhang, San Jose, CA (US)

(21) Appl. No.: 14/512,073

(22) Filed: Oct. 10, 2014

(51) Int. Cl. H05K 1/02; H05K 3/28; H05K 3/00; B29C 53/04; B05D 3/00

(52) U.S. Cl. CPC H05K 1/028; B29C 53/04; B05D 3/002; H05K 1/0296; H05K 3/0014; H05K 3/28; B29L 2031/3425

(57) ABSTRACT

A flexible substrate may be provided with an array of holes and conductive traces that extend along the flexible substrate between the holes. The flexible substrate may form part of a display or other component in an electronic device. The conductive traces may be metal traces that have meandering path shapes to resist damage upon bending. A polymer coating may be applied over the metal traces to align a neutral stress plane with the metal traces and to serve as a moisture barrier. The holes may allow the flexible substrate to twist and form a three-dimensional shape as the flexible substrate is bent. A rigid or flexible protective coating may be formed by depositing a liquid polymer precursor on the flexible substrate and curing the liquid polymer precursor.

### BACKGROUND

This relates generally to electronic devices, and, more particularly, to flexible substrates in electronic devices.

Electronic devices such as cellular telephones, computers, and other electronic equipment often contain flexible substrates. The ability to bend a flexible substrate allows the substrate to be used in situations in which rigid substrates would be difficult or impossible to use.

Flexible substrates may be used for components such as displays and touch sensors. Flexible substrates may also be used in forming flexible printed circuits. Flexible printed circuits may be used to interconnect electrical components and can be used in forming signal bus cables. Signal traces may be formed on these flexible substrates to carry signals.

Challenges can arise when the traces on a flexible substrate are bent. If flexible substrates are bent too tightly, layers of material that make up the substrate may crack or become winkled or may otherwise become damaged. A large minimum bend radius may be established for a flexible substrate to avoid damage, but this can make it difficult or impossible to accommodate the flexible substrate within a device.

It would therefore be desirable to be able to provide improved techniques for facilitating the bending of flexible substrates.

### SUMMARY

A flexible substrate may be provided with an array of holes and conductive traces that extend along the flexible substrate between the holes. The flexible substrate may form part of a display or other component in an electronic device.

The conductive traces may be metal traces that have meandering path shapes to resist damage upon bending. Meandering traces may, for example, have serpentine shapes with curved segments or zigzag shapes. The traces on the flexible substrate may be separated by intervening holes or may be organized in sets of metal traces that are not separated by any holes.

A polymer coating may be applied over the metal traces to align a neutral stress plane with the metal traces and to serve as a moisture barrier.

The holes may allow the flexible substrate to twist and form a three-dimensional shape as the flexible substrate is bent. The ability to form the three-dimensional shape that is provided by the holes may help enhance the flexibility of the flexible substrate. A protective coating may be formed by depositing a liquid polymer precursor on the flexible substrate and curing the liquid polymer precursor to form a rigid or flexible polymer coating.

### BRIEF DESCRIPTION OF THE DRAWINGS

FIG. 1 is a perspective view of an illustrative electronic device in accordance with an embodiment.

FIG. 2 is a top view of an illustrative electronic device display with a flexible substrate in accordance with an embodiment.

FIG. 3 is a cross-sectional view of a conductive trace on a flexible substrate that has been coated with a layer of material such as polymer in accordance with an embodiment.

FIG. 4 is a cross-sectional side view of an illustrative flexible substrate with a bend in accordance with an embodiment.

FIG. 5 is a cross-sectional side view of an illustrative flexible substrate with a bend that has been made at less than a right angle in accordance with an embodiment.

FIG. 6 is a cross-sectional side view of an illustrative flexible substrate with two right-angle bends in accordance with an embodiment.

FIG. 7 is a cross-sectional side view of an illustrative flexible substrate with a curved bend in accordance with an embodiment.

FIG. 8 is a top view of an illustrative substrate with slits to accommodate expansion of the substrate into a three-dimensional shape when bent or stretched in accordance with an embodiment.

FIG. 9 is a top view of the substrate of FIG. 8 following stretching in accordance with an embodiment.

FIG. 10 is a diagram of an illustrative flexible substrate with openings that have allowed the substrate to expand into a three-dimensional shape to accommodate stretching and bending in accordance with an embodiment.

FIG. 11 is a cross-sectional view of an illustrative planar flexible substrate without openings that has been bent around a cylindrical structure in accordance with an embodiment.

FIG. 12 is a diagram of an illustrative flexible substrate with openings that allow the flexible substrate to expand into a three-dimensional shape when bent around a cylindrical structure in accordance with an embodiment.

FIG. 13 is a perspective view of an illustrative flexible substrate with holes in accordance with an embodiment.

FIG. 14 is a top view of an illustrative flexible substrate with an array of diamond-like holes in accordance with an embodiment.

FIG. 15 is a top view of an illustrative flexible substrate with an array of W-shaped holes in accordance with an embodiment.

FIG. 16 is a top view of an illustrative flexible substrate with an array of slot-shaped holes in accordance with an embodiment.

FIG. 17 is a top view of an illustrative flexible substrate with an array of holes arranged in a pattern that accommodates serpentine traces in accordance with an embodiment.

FIG. 18 is a top view of an illustrative flexible substrate with an array of holes arranged in another pattern that accommodates serpentine traces in accordance with an embodiment.

FIG. 19 is a top view of an illustrative flexible substrate with an array of holes arranged in a pattern that accommodates mirrored serpentine traces in accordance with an embodiment.

FIG. 20 is a top view of an illustrative flexible substrate with an array of holes arranged in another pattern that accommodates mirrored serpentine traces in accordance with an embodiment.

FIG. 21 is a top view of an illustrative flexible substrate with an array of holes arranged in a pattern that accommodates double sine wave traces in accordance with an embodiment.

FIG. 22 is a top view of an illustrative flexible substrate with an array of holes arranged in a pattern that accommodates mirrored temple gate traces in accordance with an embodiment.

FIG. 23 is a top view of an illustrative flexible substrate with an array of holes arranged in pattern that accommodates zigzag traces in accordance with an embodiment.

FIG. 24 is a top view of an illustrative flexible substrate with an array of holes arranged in a pattern that accommodates mirrored zigzag traces in accordance with an embodiment.

FIG. 25 is a top view illustrative flexible substrate with an array of holes arranged in a pattern that accommodates doubled zigzag traces in accordance with an embodiment

FIG. 26 is a diagram of a portion of a flexible substrate with an array of holes to promote bending showing how traces may be arranged in sets of multiple parallel traces that are bordered by the same sets of holes in accordance with an embodiment.

FIG. 27 is a top view of a portion of a flexible substrate with an array of holes to promote bending in accordance with an embodiment.

FIG. 28 is a cross-sectional side view of the substrate of FIG. 26 showing how portions of the substrate may be undercut during processing in accordance with an embodiment.

FIG. 29 is a cross-sectional side view of an illustrative flexible substrate showing how the arrays of holes in a flexible substrate may pass only part way through the substrate in accordance with an embodiment.

FIG. 30 is a diagram showing how an edge portion of an illustrative flexible substrate may be free of traces in accordance with an embodiment.

FIG. 31 is a flow chart of illustrative steps involved in forming flexible substrates with arrays of openings in accordance with an embodiment.

FIG. 32 is a flow chart showing illustrative steps involved in forming flexible substrates that are protected with coating layers in accordance with an embodiment.

### DETAILED DESCRIPTION

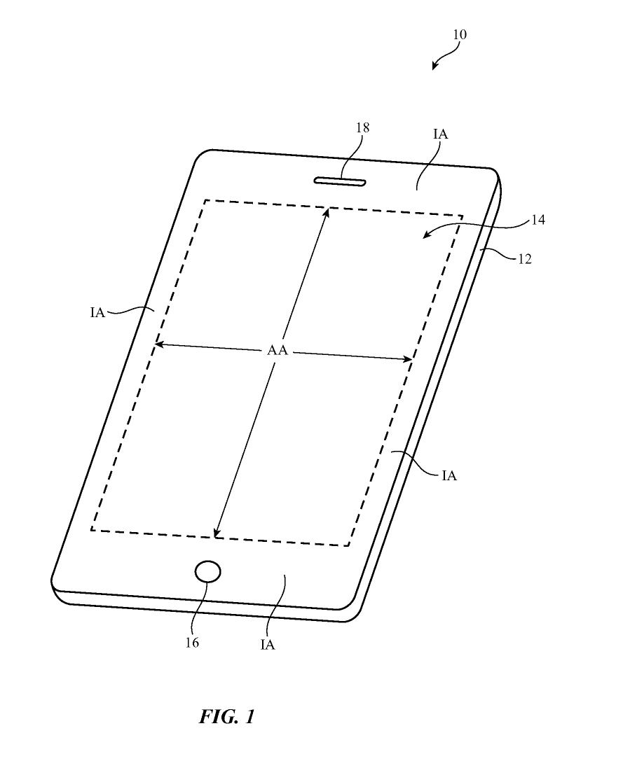

An electronic device such as electronic device 10 of FIG. 1 may contain flexible substrates. Conductive traces on the flexible substrates may be used to carry signals. The conductive traces may be bent when a portion of the flexible substrate is bent. To help reduce the minimum bend radius for a flexible substrate, a flexible substrate may be provided with holes that allow the substrate to take on a three-dimensional shape when bent. The holes allow the substrate to achieve a smaller bend radius than would be possible when bending a planar two-dimensional substrate along a bend axis.

Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, equipment that implements the functionality of two or more of these devices, or other electronic equipment. In the illustrative configuration of FIG. 1, device 10 is a portable device such as a cellular telephone, media player, tablet computer, or other portable computing device. Other configurations may be used for device 10 if desired. The example of FIG. 1 is merely illustrative.

In the example of FIG. 1, device 10 includes a display such as display 14 mounted in housing 12. Housing 12, which may sometimes be referred to as an enclosure or case, may be formed of plastic, glass, ceramics, fiber composites, metal (e.g., stainless steel, aluminum, etc.), other suitable materials, or a combination of any two or more of these materials. Housing 12 may be formed using a unibody configuration in which some or all of housing 12 is machined or molded as a single structure or may be formed using multiple structures (e.g., an internal frame structure, one or more structures that form exterior housing surfaces, etc.).

Display 14 may be a touch screen display that incorporates a layer of conductive capacitive touch sensor electrodes or other touch sensor components (e.g., resistive touch sensor components, acoustic touch sensor components, force-based touch sensor components, light-based touch sensor components, etc.) or may be a display that is not touch-sensitive. Capacitive touch screen electrodes may be formed from an array of indium tin oxide pads or other transparent conductive structures.

Display 14 may be protected using a display cover layer such as a layer of transparent glass or clear plastic. Openings may be formed in the display cover layer. For example, an opening may be formed in the display cover layer to accommodate a button such as button 16. An opening may also be formed in the display cover layer to accommodate ports such as speaker port 18. Openings may be formed in housing 12 to form communications ports (e.g., an audio jack port, a digital data port, etc.), to form openings for buttons, etc.

Display 14 may include an array of display pixels formed from liquid crystal display (LCD) components, an array of electrophoretic pixels, an array of plasma pixels, an array of organic light-emitting diode pixels or other light-emitting diodes, an array of electrowetting pixels, or pixels based on other display technologies. The array of pixels of display 14 forms an active area AA. Active area AA is used to display images for a user of device 10. Active area AA may be rectangular or may have other suitable shapes. Inactive border area IA may run along one or more edges of active area AA. Inactive border area IA may contain circuits, signal lines, and other structures that do not emit light for forming images.

It may sometimes be desirable to bend flexible substrates within device 10 to minimize inactive area IA for aesthetic reasons, to accommodate components within device 10, or to satisfy other design constraints. A flexible substrate that forms part of display 14 may, for example, be bent along one or more of its edges to minimize inactive area IA (e.g., to make display 14 borderless or nearly borderless or to otherwise help accommodate display 14 within device 10). Touch sensor substrates, substrates that include integrated display and touch sensor components, flexible printed circuits, and other flexible substrates may be bent.

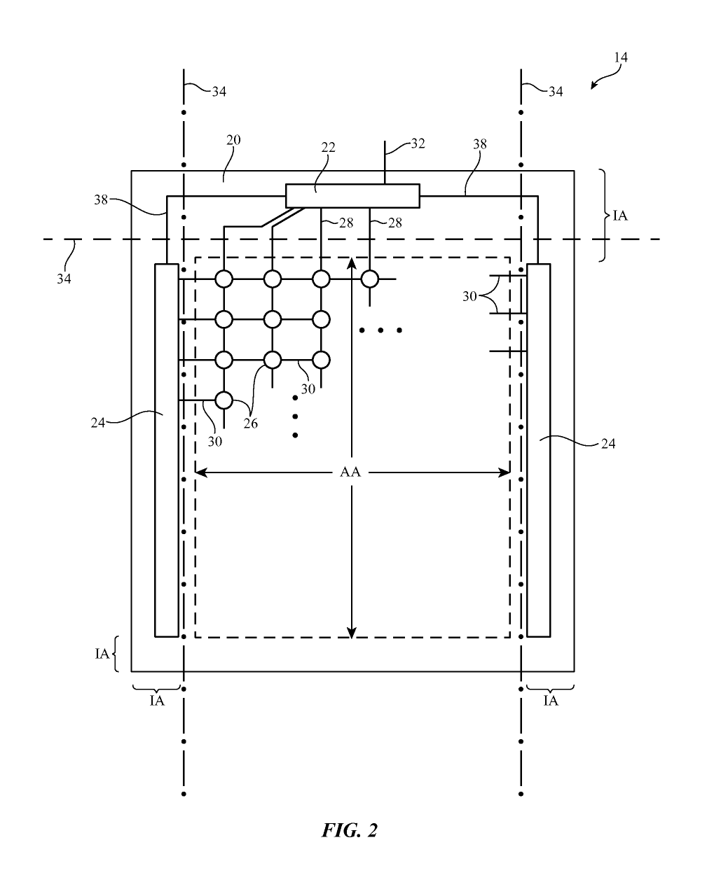

An illustrative display for device 10 is shown in FIG. 2. As shown in FIG. 2, display 14 may include layers such as flexible substrate layer 20. Substrate layers such as layer 20 may be formed from one or more layers of flexible polymer or other flexible materials. Flexible substrate 20 may have left and right vertical edges and upper and lower horizontal edges. If desired, substrates such as substrate 20 may have non-rectangular shapes (e.g., shapes with curved edges, rectangular shapes and other shapes with protrusions that form flexible tails, etc.).

Display 14 may have an array of pixels 26 for displaying images for a user. Each pixel may, for example, have a light-emitting diode (e.g., an organic light-emitting diode). Pixels 26 may be arranged in rows and columns. There may be any suitable number of rows and columns in the array of pixels 26 (e.g., ten or more, one hundred or more, or one thousand or more). Display 14 may include pixels 26 of different colors. As an example, display 14 may include red pixels that emit red light, green pixels that emit green light, blue pixels that emit blue light, and white pixels that emit white light. Configurations for display 14 that include pixels of other colors may be used, if desired.

Display driver circuitry may be used to control the operation of pixels 26. The display driver circuitry may be formed from integrated circuits, thin-film transistor circuits, or other suitable circuitry. As shown in FIG. 2, display 14 may have display driver circuitry such as circuitry 22 that that contains communications circuitry for communicating with system control circuitry over path 32. Path 32 may be formed from traces on a flexible printed circuit or other cable. If desired, some or all of circuitry 22 may be mounted on a substrate that is from substrate 20. The control circuitry with which circuitry 22 communicates may be located on one or more printed circuits in electronic device 10. During operation, the control circuitry may supply display 14 with information on images to be displayed on display 14 by pixels 26.

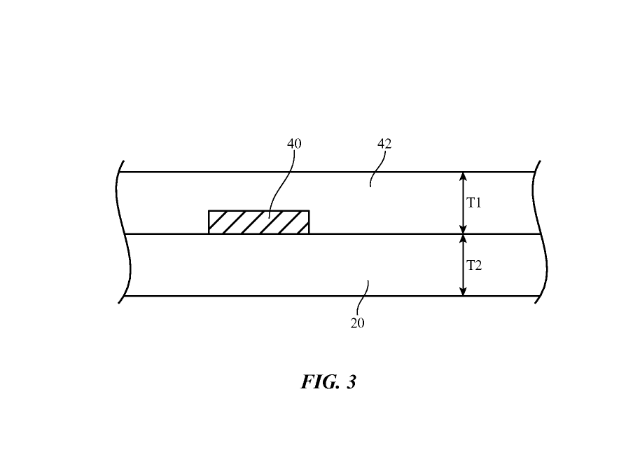

To display the images on pixels 26, display driver circuitry 22 may supply corresponding image data to data lines 28 while issuing clock signals and other control signals to supporting display driver circuitry such as gate driver circuitry 24 using signal lines 38. Data lines 28 are associated with respective columns of display pixels 26. Gate driver circuitry 24 (sometimes referred to as scan line driver circuitry) may be implemented as part of an integrated circuit and/or may be implemented using thin-film transistor circuitry on substrate 20. Horizontal signal lines such as gate lines 30 (sometimes referred to as scan lines or horizontal control lines) run horizontally through display 14. Each gate line 30 is associated with a respective row of pixels 26. If desired, there may be multiple horizontal control lines such as gate lines 30 associated with each row of pixels 26. Gate driver circuitry 24 may be located on the left side of display 14, on the right side of display 14, or on both the right and left sides of display 14, as shown in FIG. 3.

To minimize the footprint of display 14, it may be desirable to bend portions of substrate 20 along one or more bend axis 34. It may also be desirable to bend a flexible substrate such as substrate 20 in situations in which substrate 20 forms part of other device structures (e.g., part of a touch sensor substrate that carries an array of capacitive touch sensor electrodes, part of a touch screen display that has both capacitive touch sensor electrodes and display pixel structures on a common substrate layer, part of a flexible printed circuit cable, part of a flexible printed circuit on which integrated circuits and other devices have been mounted, or part of other device structures).

To help prevent damage to the conductive traces on substrate 20 during bending, it may be desirable to cover these traces with a coating layer such as a layer of polymer. As shown in FIG. 3, for example, conductive trace 40 (e.g., traces 28, 38, 30 or other traces) on flexible substrate 20 may be covered with a dielectric layer such as polymer layer 42.

Conductive traces such as trace 40 may be formed from metal (e.g., copper, aluminum, silver, gold, molybdenum, etc.) or conductive polymer. The traces can be passivated. The conductive traces may, if desired, be formed from multilayer stacks of metals or other materials (e.g., titanium/aluminum/titanium, etc.). Conductive traces 40 may also be formed from other types of coated or printed materials such as silver nanowires, conductive inks such as silver inks or other metal inks, carbon nanotubes, carbon inks, etc.

Substrate layer 20 may be a sheet of polyimide, polyester, polyethylene napthalate, or other polymer. Substrate layer 20 may also be formed from composite films, metal foils, thin glass, or combinations of these materials. Polymer coating layer 42 may be a high performance polymer barrier film that provides corrosion protection or other suitable flexible polymer layer. The thicknesses T1 and T2 of layers 42 and 20 may be selected so that the neutral stress plane of the stack of layers in FIG. 3 is aligned with trace 40, thereby helping to minimize stress when traces 40 are bent.

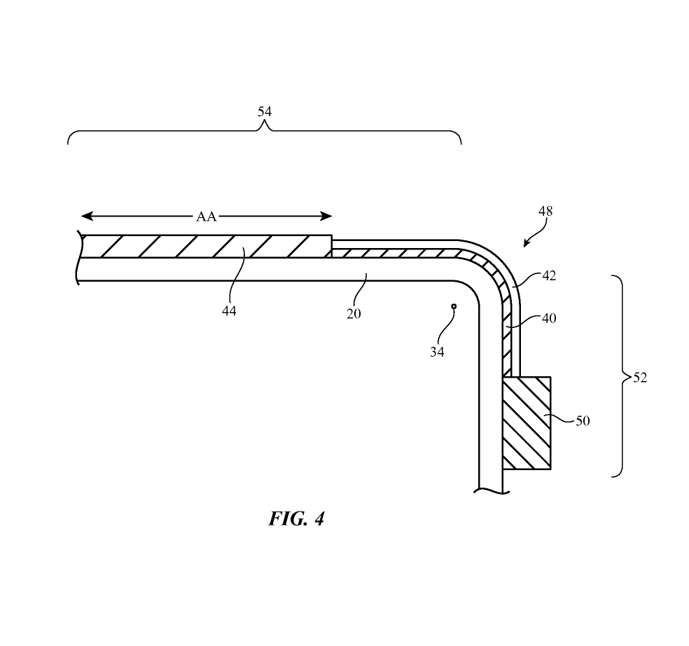

FIG. 4 is a cross-sectional side view of a flexible substrate on which traces such as trace 40 have been bent. In the example of FIG. 4, flexible substrate 20 is part of a display (display 14) that has active area components 44 (e.g., pixels 26). This is merely illustrative. Flexible substrate 20 may form part of any suitable structure in device 10.

Substrate 20 may be planar (unbent) in main region 54 or may have a slight curve in region 54. Bent edge region 52 of substrate 20 may be bent downwards about bend axis 34 to form bend 48 in substrate 20. Conductive traces such as trace 40 and polymer coating 42 bend with substrate 20. Traces 40 may be elongated traces that extend along a dimension that is perpendicular to bend axis 34. Circuitry 50 (e.g., display driver circuitry, touch sensor circuity in a touch sensor, etc.) may be mounted on bent edge region 52 and/or a flexible printed circuit cable or other component may be attached to substrate 20 in bent edge region 52.

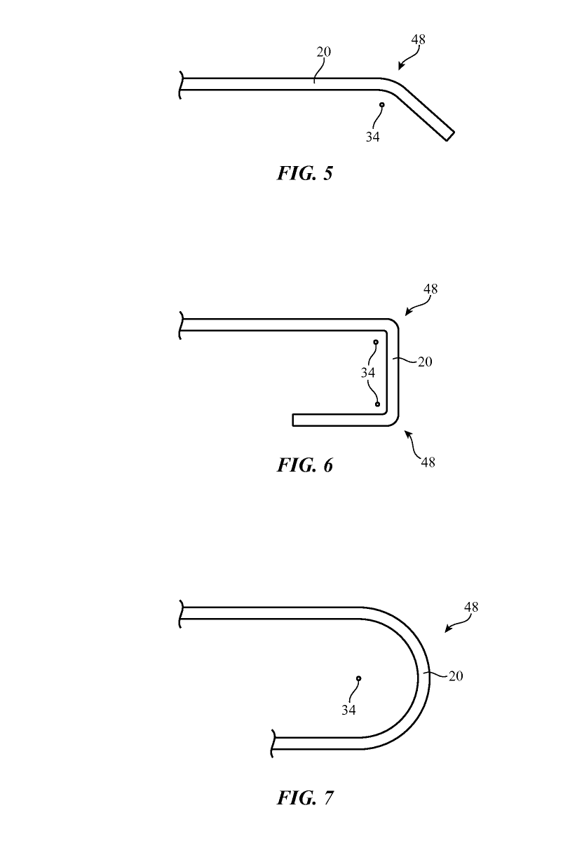

Substrate 20 may be bent along one or more edges and/or along one or more bend axes. In the example of FIG. 5, substrate 20 has been bent sufficiently to ease the edge of substrate 20, but the bend angle of bend 48 is less than a right angle. In FIG. 6, there are two bends 48 each formed by bending a portion of substrate 20 about a different respective bend axis 34. FIG. 7 shows how substrate 20 may be bent about bend axis 34 to form a 180° bend. The examples of FIGS. 4, 5, 6, and 7 are merely illustrative. Any suitable type of bend may be formed in flexible substrate 20, if desired.

Substrate 20 may contain one or more layers. For example, substrate 20 may include one or more polymer layers interleaved with one or more layers of conductive traces. The bending of flexible substrate 20 creates bends in the conductive traces on substrate 20 and creates bends in the polymer layers. Unless care is taken, layers of material in a bent substrate may crack on the outer surface of a bend while buckling on the inner surface of the bend. These deformations of the layers in a bent substrate may prevent the substrate from being bent with a small bend radius.

In accordance with an embodiment, substrate 20 is provided with holes that facilitate bending of substrate 20 while avoiding damage such as cracks, buckling layers, and layer delamination. The holes may be formed from slits in the substrate (e.g. slits that expand to form substrate openings when the substrate is bent and stretched), may be formed openings that pass entirely through the substrate (i.e., through holes), or may be formed from holes that pass partway through the substrate.

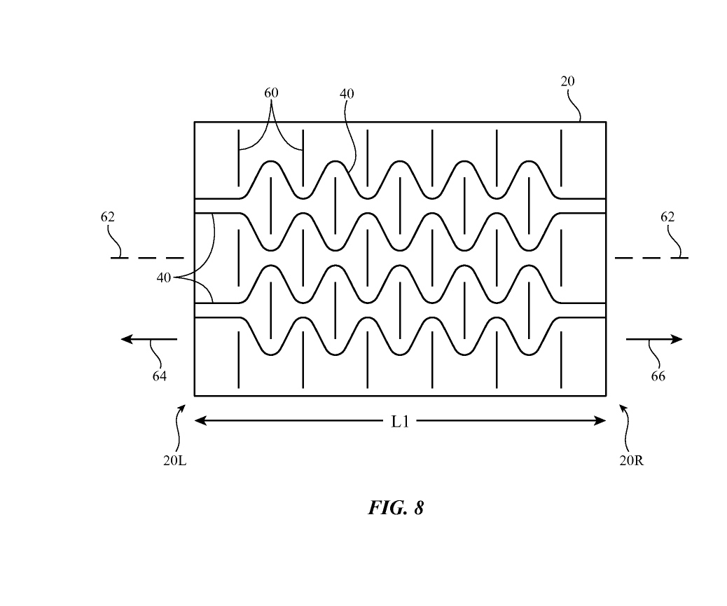

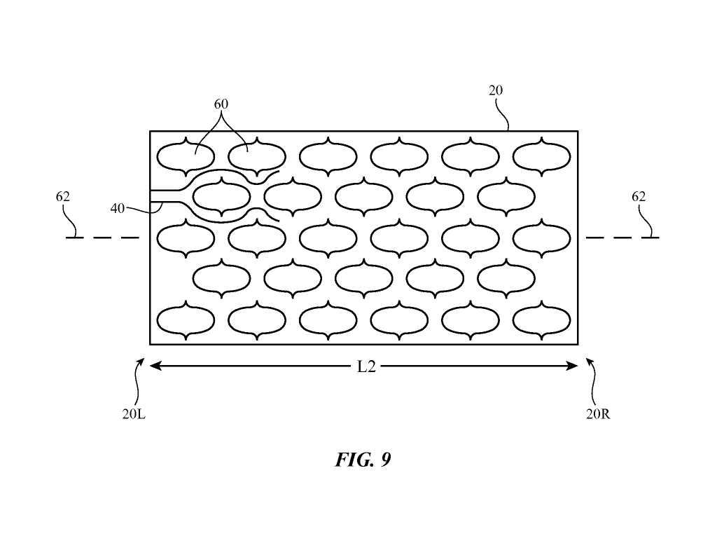

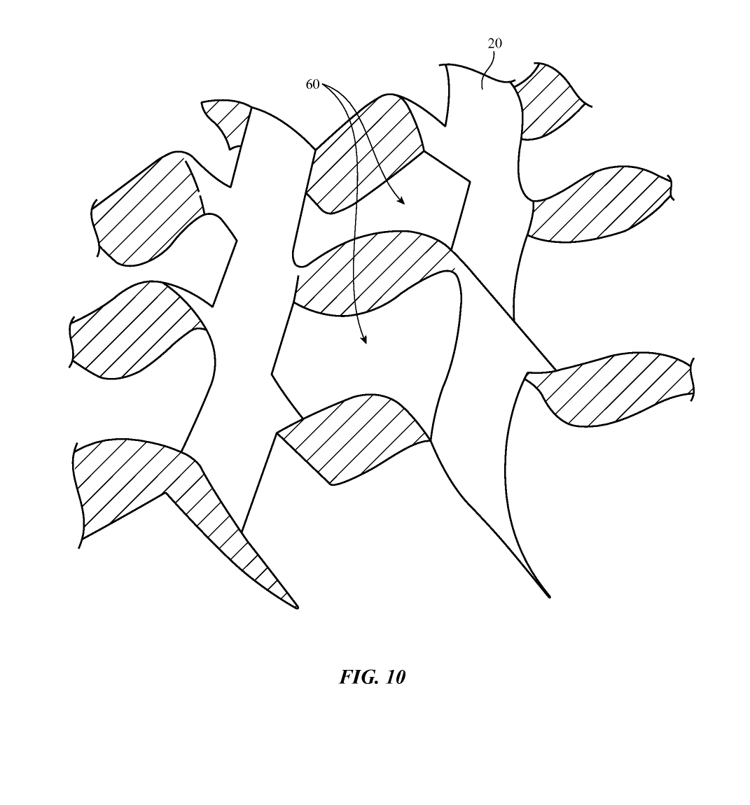

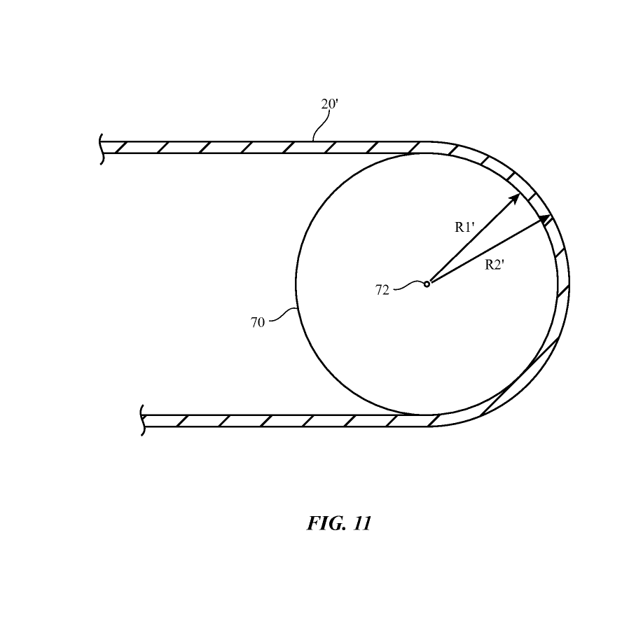

The ability of holes to facilitate stretching and bending is illustrated in the example of FIGS. 8 and 9. FIG. 8 is a top view of substrate 20 in a configuration in which substrate 20 has not been stretched or bent. Conductive traces 40 may have sine wave shapes or other serpentine shapes and may extend along longitudinal dimension 62 (e.g., a dimension that is perpendicular to the bend axis around which substrate 20 will be bent to form bend 48). The pattern of traces 40 that is used on substrate 20 allows multiple signals to be carried in parallel. Each trace 40 may carry a respective signal. In the example of FIG. 8, holes 60 are slit-shaped openings that extend along a lateral dimension that is perpendicular to longitudinal dimension 62. Holes 60 are arranged in an array with a pattern that accommodates the serpentine shape of traces 40.

Initially, substrate 20 may have an unstretched length L1 between ends 20L and 20R. When end 20L is pulled in direction 64 and end 20R is pulled in direction 66, substrate 20 will stretch so that its length increases from initial length L1 to a larger stretched length L2, as shown in FIG. 9. In this configuration, the slit shapes of holes 60 have expanded to form larger openings and substrate 20 has twisted out of the plane of the page, creating a three-dimensional shape for substrate 20. This shape preserves the ability of traces 40 to convey signals, while enhancing the flexibility of substrate 20.

FIG. 10 is a perspective view of an illustrative section of a flexible substrate 20 in a configuration in which substrate 20 has been stretched sufficiently to cause substrate 20 to twist out of the plane of its initial shape to acquire a three-dimensional shape (i.e., a shape with a significantly enhanced thickness perpendicular to the plane of the initially planar flexible substrate).

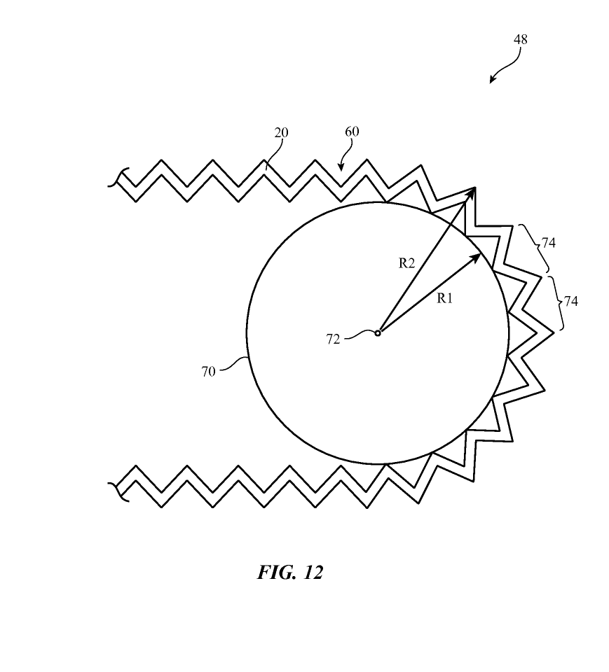

FIGS. 11 and 12 illustrate the different behaviors exhibited by a planar flexible substrate without holes (i.e., substrate 20′ of FIG. 11) and a planar flexible substrate with holes 60 that has been stretched and bent (i.e., substrate 20 of FIG. 12).

As shown in FIG. 11, substrate 20′ may be bent around a support structure such as illustrative cylindrical support structure 70. The thickness of the portion of substrate 20′ that bends around structure 70 can be measured by subtracting inner radius R1′ (the distance from support structure center 72 to the inner surface of substrate 20′) from outer radius R2′ (the distance from support structure center 72 to the outer surface of substrate 20′). As shown in FIG. 11, this thickness is relatively small (e.g., the thickness of substrate 20′ may range between the thickness of a single layer flexible printed circuit and the thickness of a multilayer flexible printed circuit).

As shown in FIG. 12, the presence of openings 60 in flexible substrate 20 allows flexible substrate 20 to twist out of the plane that would be associated with a thin substrate with no openings. As a result, substrate 20 acquires a three-dimensional shape with undulations 74 so that the overall thickness of substrate 20 (R2−R1) is larger than the thickness of substrate 20′ (R2′−R1′) even in a configuration in which substrate 20 is formed from the same number of layers of dielectric and metal traces that make up substrate 20′. The twisting motion that gives rise to undulations 74 and the three-dimensional shape for substrate 20 enhances the ability of substrate 20 to form bend 48.

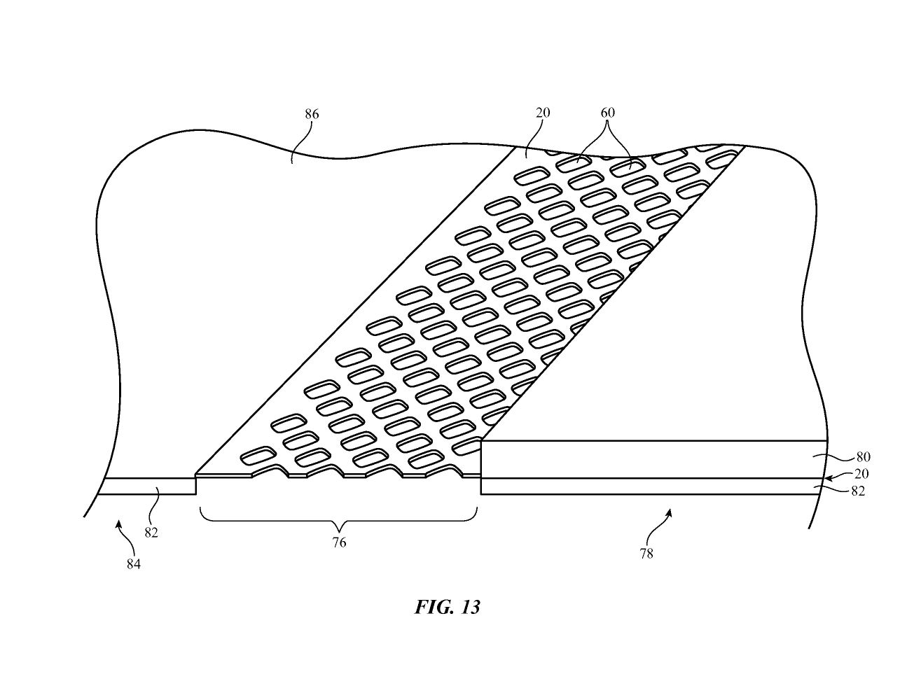

FIG. 13 is a perspective view of flexible substrate 20 in a configuration in which flexible substrate 20 has an array of diamond-shaped openings 60. In the example of FIG. 13, flexible substrate 20 extends between structures 78 and structures 84. Portion 76 of substrate 20 has openings 60 and is flexible, facilitating bending around a bend axis to form bend 48. In structures 78, substrate 20 may be interposed between layer 80 and layer 82. Structures 78 may form active area AA for display 14. Layer 80 may be a polarizer layer. Substrate 20 in structures 78 may have an array of pixels 26 and other display structures for display 14. Layer 82 may be a polymer backing layer that provides structures 78 with support (e.g., to stiffen structures 78). Structures 84 may include layer 86 and layer 82. Layer 86 may be a substrate to which one or more integrated circuits are mounted (e.g., display driver circuitry 22 of FIG. 2). Layer 82 may be a polymer backing layer. When installed in device 10, flexible portion 76 of substrate 20 may exhibit a bend of the type shown in FIG. 7.

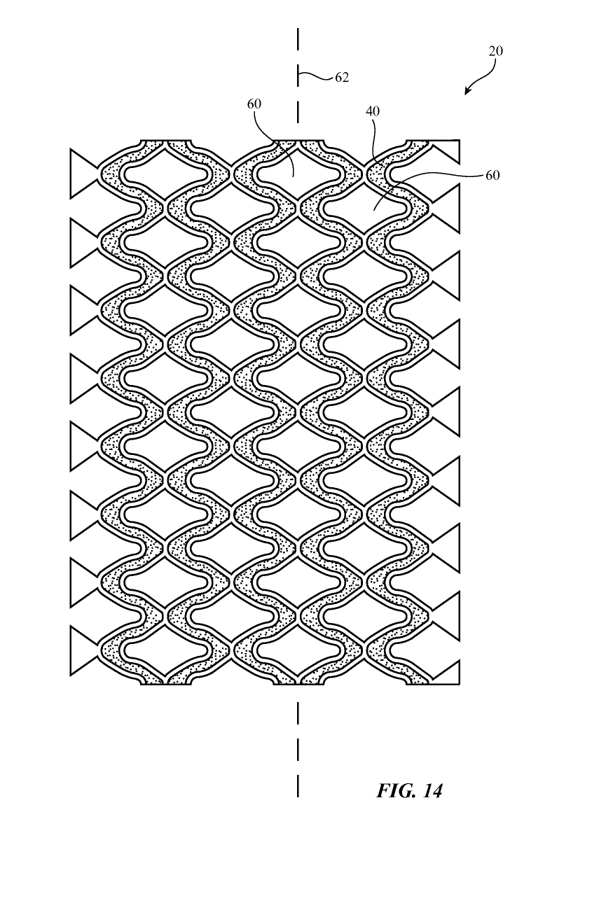

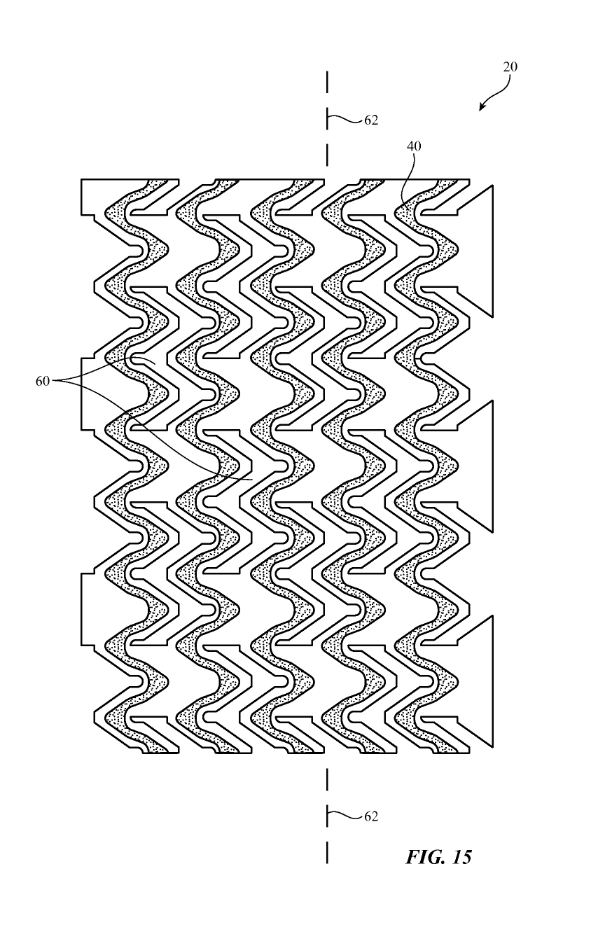

Openings 60 may have the shapes of circles, ovals, slots, rectangles, triangles, shapes with straight sides, shapes with curved sides, shapes with combinations of curved and straight sides, or other suitable shapes. Openings 60 may be organized in an array having rows and columns, may be placed within substrate 20 in a pseudorandom pattern, or may have other suitable patterns. FIGS. 14-24 show illustrative patterns of holes 60 and traces 40 that may be used in forming substrate 20. These are merely examples. Other suitable hole configurations and trace configurations may be used in forming flexible substrate 20 if desired.

In the example of FIG. 14, holes 60 are formed in an array that provides flexible substrate 20 with set of diagonally crossed portions. Holes 60 may have diamond-like shapes. Mirrored temple gate traces such as trace 40 may run along longitudinal axis 62 between openings 60. Mirrored temple gate trace shapes and other meandering path shapes (e.g., serpentine shapes) for traces 40 may have a spring-like quality that allows traces with these shapes to stretch more without cracking than straight traces. Mirrored temple gate traces may have curved segments, straight (zigzag) segments, or may have other meandering path shapes.

In the example of FIG. 15, openings 60 have W shapes. Temple gate traces such as trace 40 or other serpentine traces may extend parallel to longitudinal axis 62 on the portions of flexible substrate 20 between openings 60.

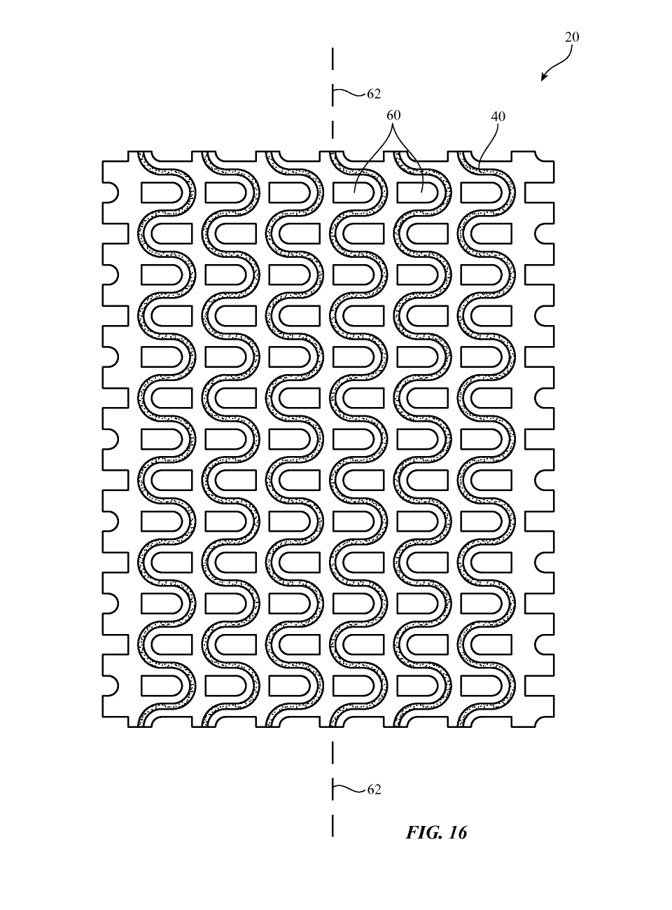

In the example of FIG. 16, openings 60 in flexible substrate 20 have slot shapes with rounded and flat ends. Traces such as serpentine trace 40 may run parallel to longitudinal axis 62.

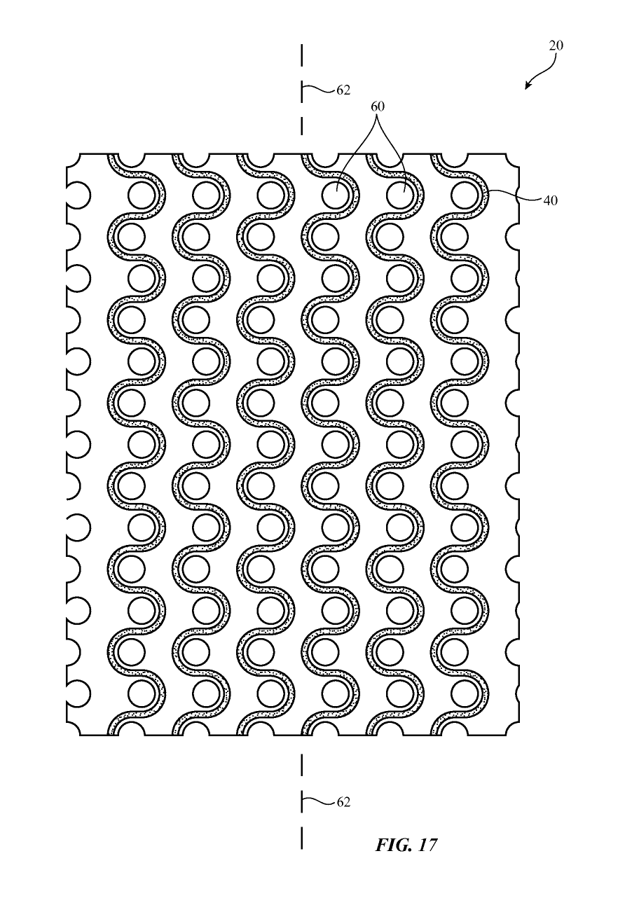

FIG. 17 shows how flexible substrate 20 may have an array of circular openings 60 that are patterned to allow traces such as serpentine trace 40 to run parallel to longitudinal axis 62.

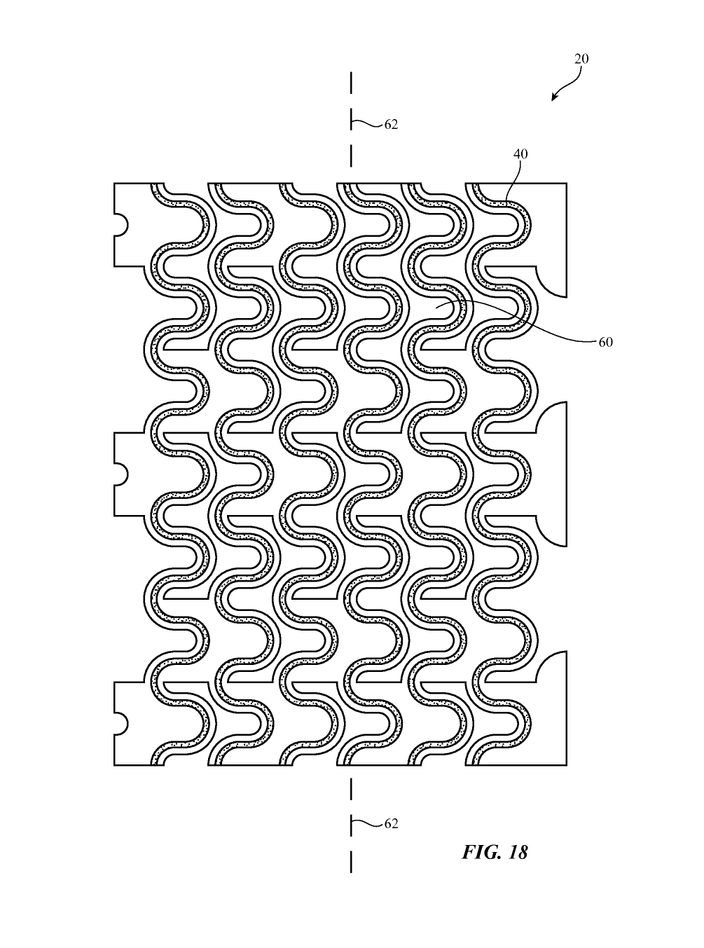

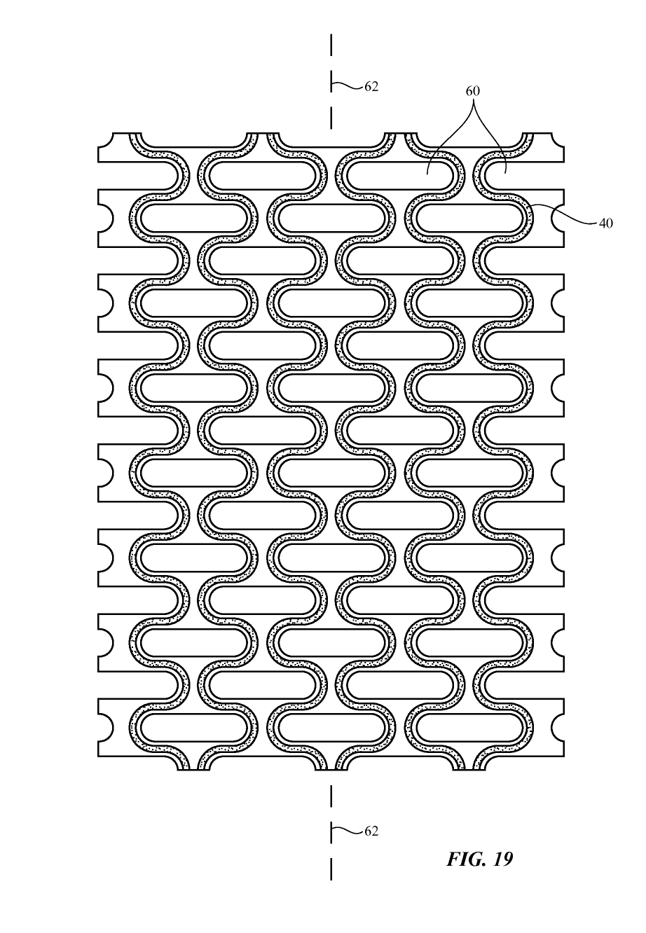

FIG. 18 shows how flexible substrate 20 may have an array of openings 60 with straight and curved edges. Traces such as serpentine traces 40 may extend along longitudinal axis 62.

Flexible substrate 20 of FIG. 19 has an array of openings 60 with straight and curved edges. Traces such as serpentine traces 40 may extend along longitudinal axis 62. In the FIG. 19 configuration, adjacent pairs of traces 40 follow mirrored paths.

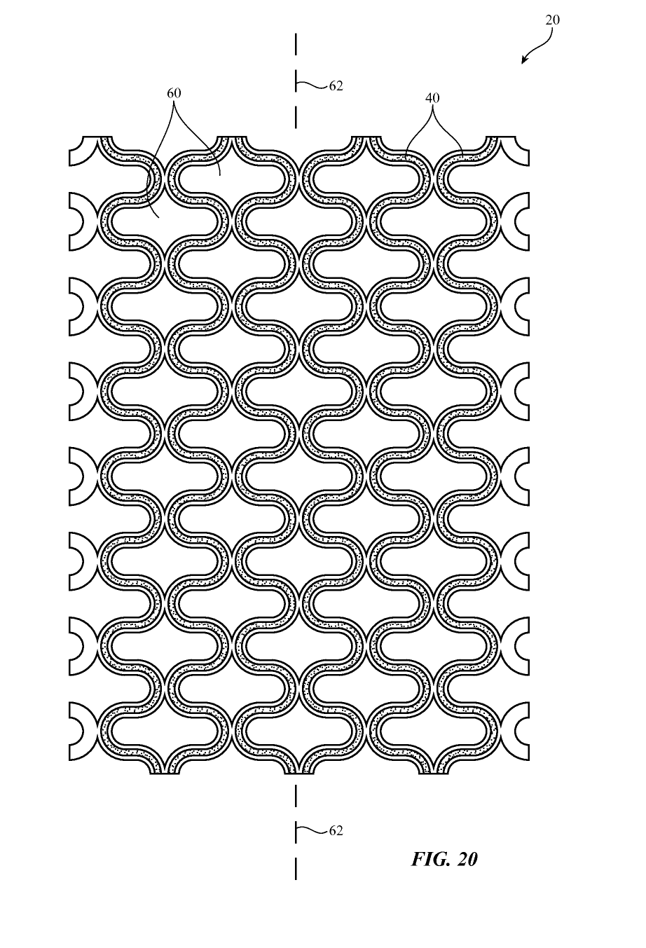

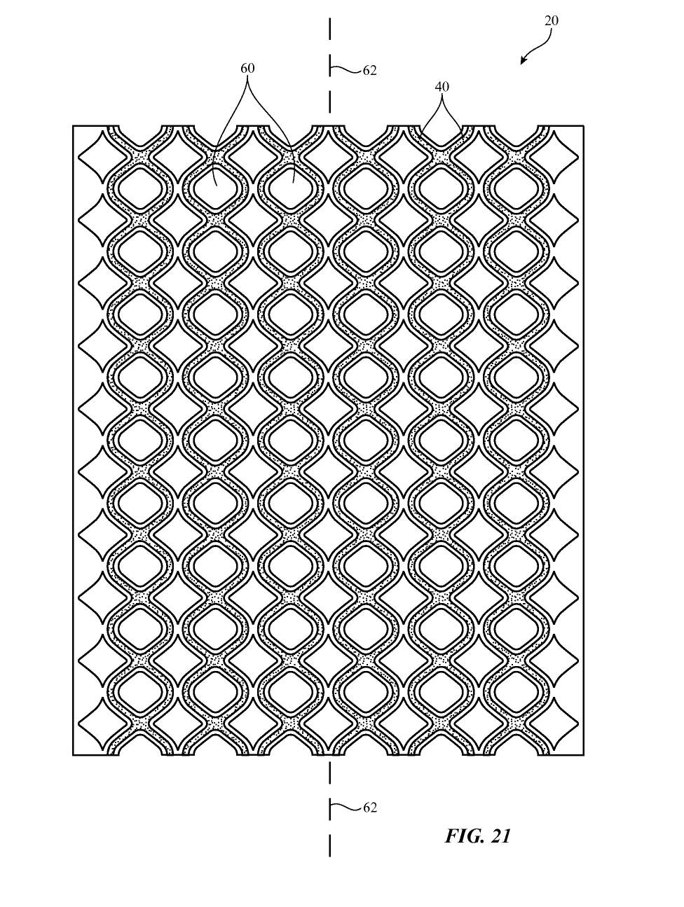

FIG. 20 is another illustrative configuration for flexible substrate 20 in which traces 40 may follow mirrored paths between openings 60 while extending along longitudinal axis 62.

In the illustrative example of FIG. 21, traces 40 have a redundant configuration in which two sine wave traces 40 periodically overlap each other. With this type of arrangement, a crack in one sine wave trace 40 will not disrupt signal flow, because the parallel portion of the redundant sine trace 40 can carry the signal in place of the cracked trace portion. Traces 40 may extend along longitudinal axis 62 and may have any suitable shape (e.g., a sine wave shape or other serpentine shape, etc.). Each trace 40 in this type of arrangement may have a chain of segments and each segment can surround one or more or holes 60.

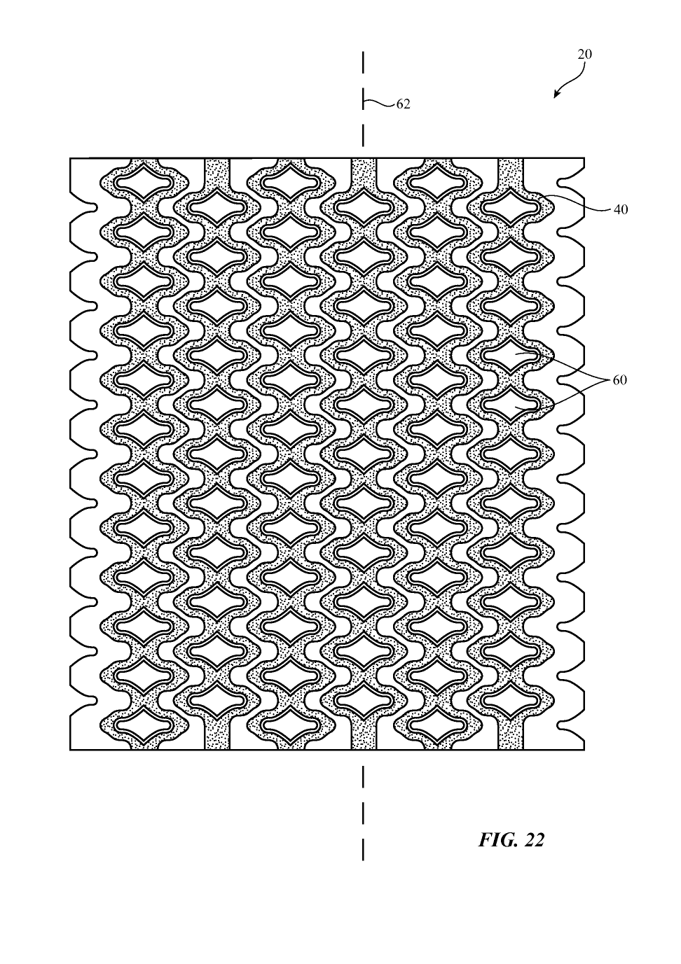

FIG. 22 is another example of a pattern that may be used for traces 40 and openings 60 in substrate 20. In the example of FIG. 22, each trace 40 has a chain of segments that surround respective openings 60. Each chain of segments (i.e., each pair of double temple gate trace lines or other pair of serpentine paths in a given trace 40) may extend along longitudinal axis 62.

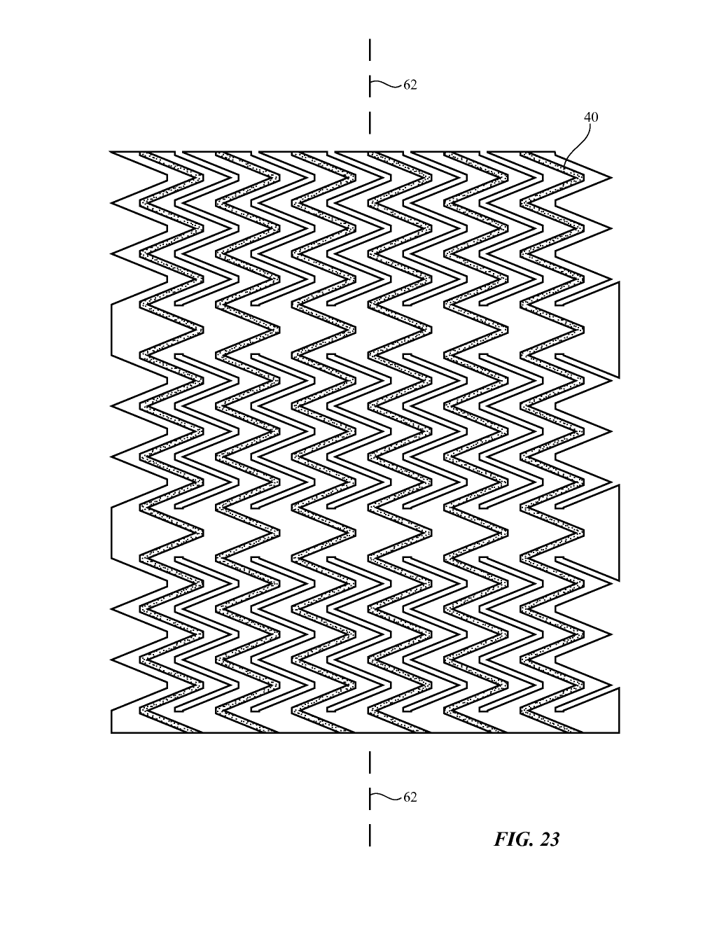

As shown in FIG. 23, flexible substrate 20 may, if desired, have multiple zigzag-shaped openings 60. Metal traces 40 may have a zigzag meandering shape extending along longitudinal axis 62.

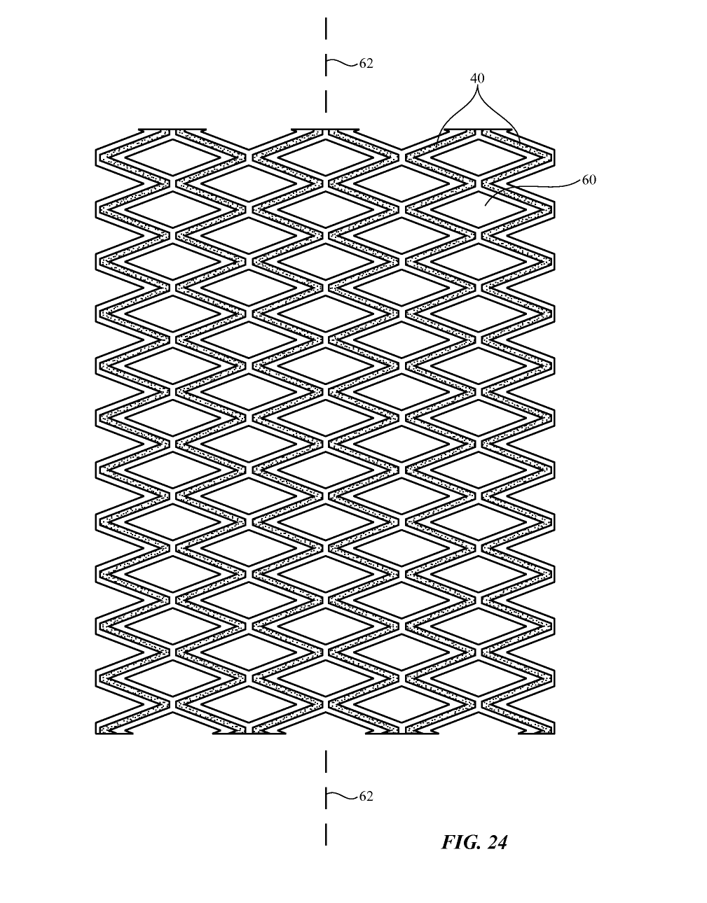

Another illustrative pattern for holes 60 and traces 40 is shown in FIG. 24. In the configuration of FIG. 24, flexible substrate 20 has an array of diamond-shaped holes 60 and mirrored zigzag traces 40 that extend along longitudinal axis 62.

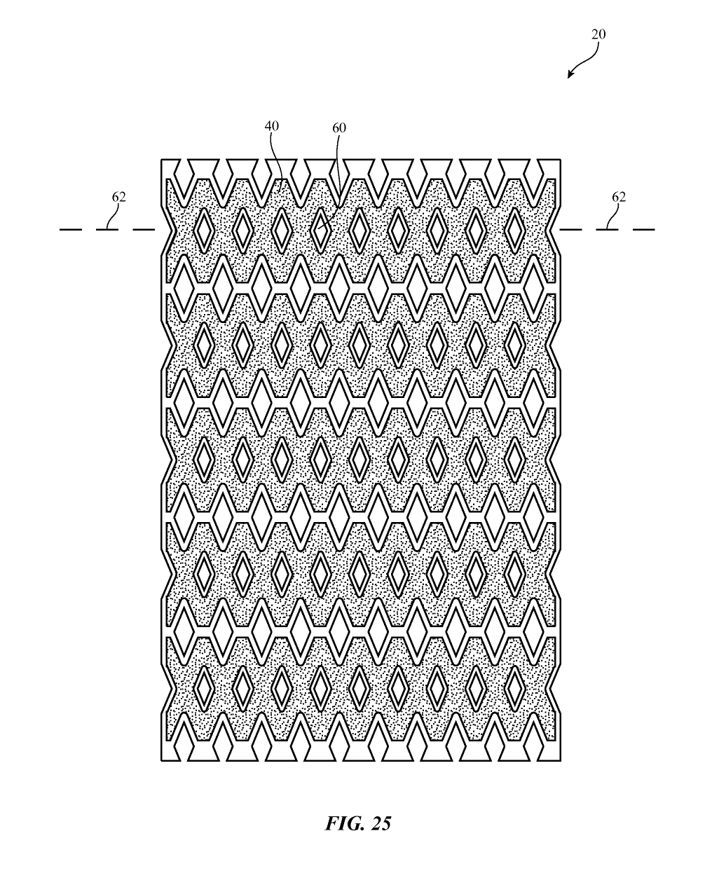

In the illustrative pattern for holes 60 and traces 40 that is shown in FIG. 25, traces 40 form double zigzag (diamond) shapes, which provides redundancy similar to the redundancy provided by a double sine wave trace shape.

In arrangements of the type shown in FIGS. 14-25, bend axis 34 (and bend 48) may be perpendicular to longitudinal axis 62, so that traces 40 are bent in a direction that stretches the meandering path shape of traces 40 lengthwise along axis 62.

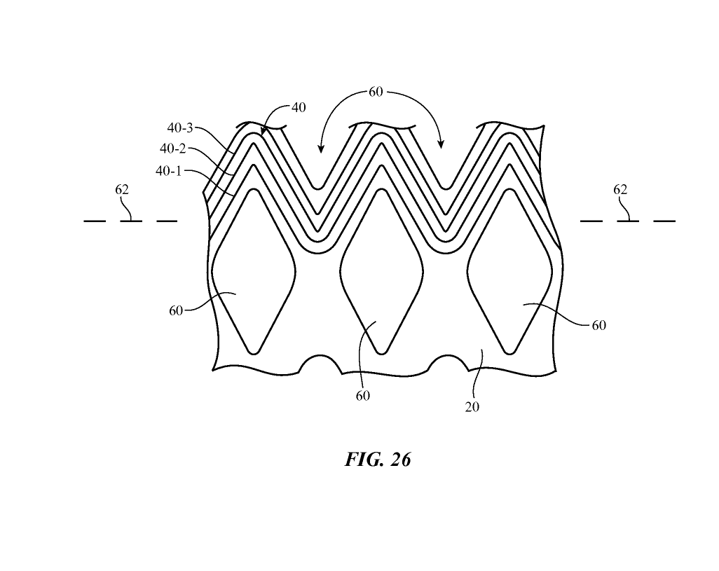

FIG. 26 shows how traces 40 may be organized in groups. In the example of FIG. 26, three traces (trace 40-1, 40-2, and 40-3) form a set of parallel traces that extend together along longitudinal axis 62 between respective openings 60 (i.e., there are openings on both opposing sides of the set of traces but none of the traces in the set are separated by an intervening hole 60). If desired, sets of traces may have two traces, three traces, four or more traces, five or more traces, 10 or more traces, fewer than 100 traces, or more than 30 traces. The traces of each set may have a meandering path shape (e.g., to resist cracking) The meandering path shape may be serpentine with curved edges or may follow a zigzag pattern (as examples). Traces 40 of FIGS. 8, 14, 15, 16, 17, 18, 19, 20, 21, 22, 23, and 24 may be individual traces (e.g., parallel traces that are separated by respective holes 60) or may be sets of traces, as described in connection with FIG. 26.

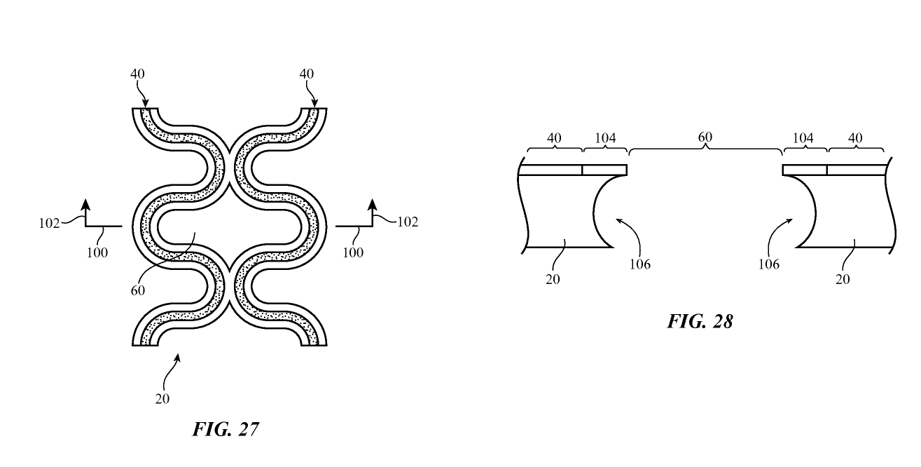

FIG. 27 is a top view of a portion of an illustrative flexible substrate. Flexible substrate 20 of FIG. 27 has an array of holes 60 and traces 40. Traces 40 may include individual traces and/or sets of traces.

A cross-sectional side view of flexible substrate 20 of FIG. 27 taken along line 100 and viewed in direction 102 is shown in FIG. 28. As shown in FIG. 28, traces 40 may be formed on substrate 20. Edge portions 104 of substrate 20 may be free of traces 40 (i.e., portions 104 may form exclusion zones). During fabrication, holes such as hole 60 may be formed by etching (e.g., a dry etch performed while mask structures are located over traces 40 and regions 104 but not over holes 60). Undercuts 106 may be formed in substrate 20 during etching. If desired, undercut portions of substrate 20 may extend under exclusion zones 104 but not under traces 40.

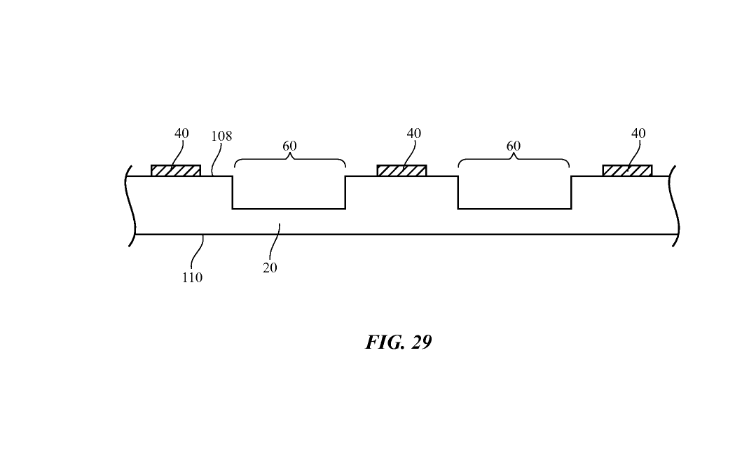

FIG. 29 shows how holes 60 need not pass entirely through substrate 20, but rather may be holes that only pass partway through substrate 20. Holes such as holes 60 of FIG. 29 that pass only partway through substrate 20 (e.g., only partway from surface 110 to opposing surface 108) may help to selectively thin substrate 20 sufficiently to enhance flexibility. In general, holes 60 may be through holes (openings that pass completely through substrate 20 from surface 110 to surface 108), may be partial holes (holes that pass only partway through substrate 20) or may include both through-hole and partial hole portions.

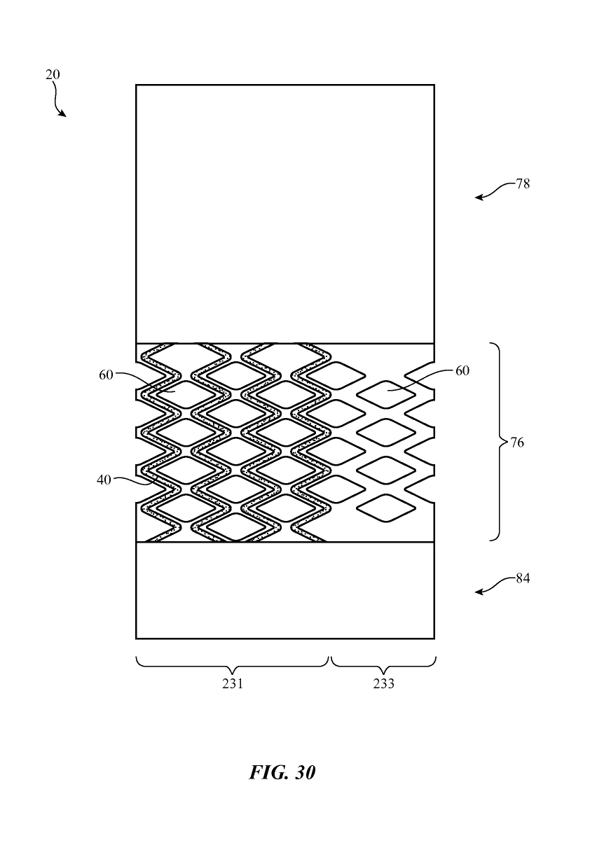

As shown in FIG. 30, metal traces 40 may be confined to central portion 231 of substrate 20 and may not be formed along edge region 233 of substrate 20. This type of approach may be helpful to prevent damage to traces 40 during handling. The same hole pattern may be used for holes 60 in region 231 with traces 40 and in region 233 without traces 40 for consistent flexibility and stretchability across the bend region.

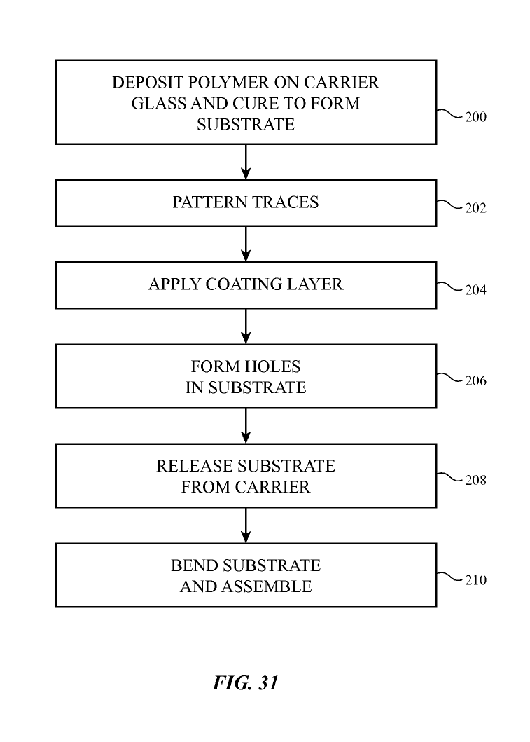

FIG. 31 is a flow chart of illustrative steps involved in forming flexible substrates such as substrate 20.

At step 200, a liquid polymer precursor may be deposited onto a glass carrier or other suitable carrier. The deposited liquid may be cured to form a polymer layer for substrate 20. Curing may be performed using heat, application of ultraviolet light or other light, chemical catalyst exposure, or other curing techniques. The polymer may be an acrylic polymer, epoxy, a urethane adhesive, silicone adhesive, or other suitable polymer materials.

Following formation of substrate 20, traces 40 may be patterned onto the upper surface of substrate 20 (step 202). Traces 40 may be formed by depositing a blanket metal film or other conductive film followed by photolithographic processing and etching. Traces 40 may also be formed using other techniques (e.g., shadow mask deposition, electroplating, etc.). If desired, substrate 20 may contain multiple layers of traces 40 and polymer layers. The use of a single polymer layer covered with traces 40 is merely illustrative.

At step 204, coating layer 42 may be deposited to align the neutral stress plane of substrate 20 with traces 40 and to provide a moisture barrier for traces 40.

Holes 60 may be formed at step 206 (e.g., using photolithography and etching, using laser cutting, using die cutting, using other cutting tools, etc.).

At step 208, substrate 20 may be released from the glass carrier.

At step 210, substrate 20 may be bent to form bend 48 and assembled with other components to form device 10.

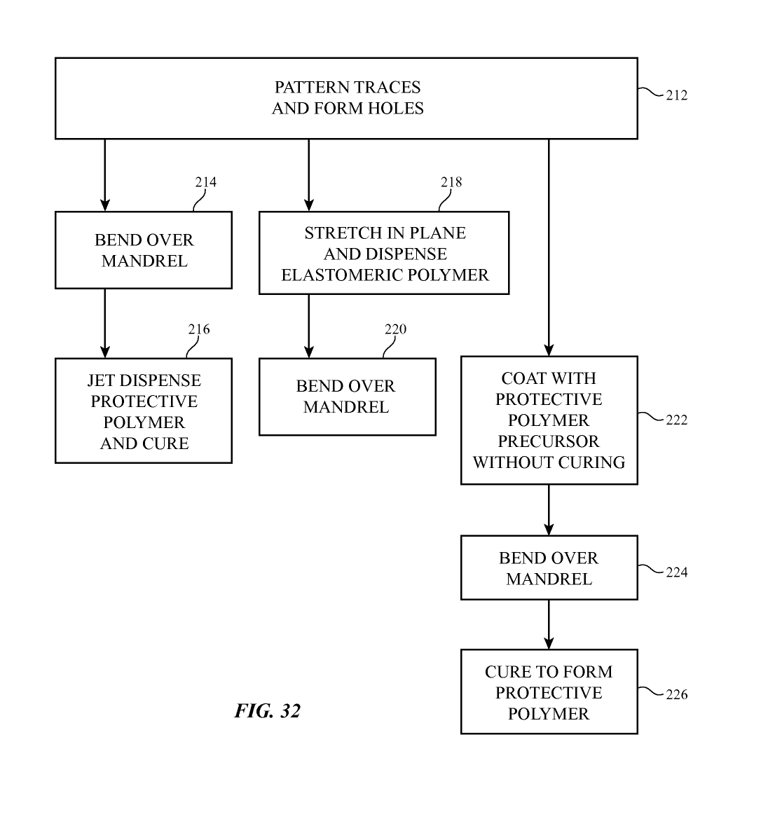

FIG. 32 is a flowchart of illustrative steps involved in protecting bend 48 of substrate 20.

During the operations of step 212, substrate 20 may be formed, patterned traces 40 may be formed on the surface of substrate 20, and holes 60 may be formed in substrate 20.

With a first approach, substrate 20 may be bent over a mandrel at step 214. The bending process forms bend 48 and holds substrate 20 in place. Holes 60 allow substrate 20 to twist and take on a three-dimensional shape while bending.

While substrate 20 is being held in place, a jet dispenser or other polymer deposition tool may be used to cover substrate 20 with a liquid polymer precursor in the portion of substrate 20 overlapping bend 48. The deposited liquid may then be cured by application of ultraviolet light, heat, etc. The cured layer of polymer that covers flexible substrate 20 in the vicinity of bend 48 may be stiff or flexible and may protect substrate 20 and traces 40 on substrate 20 from damage. The protective polymer layer may be provided on substrate 20 instead of layer 42 or in addition to layer 42.

With a second approach, substrate 20 may be stretched while being maintained in a planar shape (step 218). While stretched, an elastomeric polymer may be deposited over substrate 20. The polymer may be deposited in liquid precursor form followed by curing using heat, ultraviolet light, chemical catalyst, etc. The elastomeric polymer that is formed over substrate 20 at step 218 may be silicone or other elastomeric polymer. At step 220, substrate 20 and the flexible elastomeric polymer protective coating on substrate 20 may be bent over mandrel to form bend 48. The protective polymer layer may be provided on substrate 20 instead of layer 42 or in addition to layer 42.

With a third approach, substrate 20 may be coated with a liquid polymer precursor at step 222.

At step 224, substrate 20 and the liquid coating on substrate 20 may be bent over a mandrel to form bend 48. Because the coating on substrate 20 is a liquid, the coating will not resist bending. At step 224, the liquid polymer precursor may be cured (e.g., using heat, a chemical catalyst, exposure to ultraviolet light or other light, etc.). The cured polymer may be flexible or rigid. If desired, the cured polymer may be sufficiently stiff to hold substrate 20 in its bent configuration. The protective polymer layer may be provided on substrate 20 instead of layer 42 or in addition to layer 42.

The foregoing is merely illustrative and various modifications can be made by those skilled in the art without departing from the scope and spirit of the described embodiments. The foregoing embodiments may be implemented individually or in any combination.

What is claimed is:

1. Apparatus, comprising:
a flexible substrate layer having holes and a bend; and
conductive traces on the flexible substrate, wherein the holes are formed between the conductive traces and wherein the flexible substrate has a three-dimensional shape formed by twisting portions of the flexible substrate layer that overlap the bend.

2. The apparatus defined in claim 1 wherein the conductive traces comprise metal traces.

3. The apparatus defined in claim 2 wherein the metal traces comprise meandering traces.

4. The apparatus defined in claim 3 wherein the metal traces extend along a longitudinal axis and wherein the bend is formed around a bend axis that is perpendicular to the longitudinal axis.

5. The apparatus defined in claim 4 wherein the metal traces are formed in sets each of which includes multiple metal traces that are not separated from each other by any holes.

6. The apparatus defined in claim 4 wherein the holes are through holes that pass between first and second opposing surfaces of the flexible substrate layer.

7. The apparatus defined in claim 4 wherein the holes are formed only partway through the flexible substrate layer.

8. The apparatus defined in claim 4 further comprising a polymer coating over the metal traces that aligns a neutral stress plane with the metal traces and that serves as a moisture barrier for the metal traces.

9. The apparatus defined in claim 4 wherein the metal traces have serpentine paths with curved segments.

10. The apparatus defined in claim 4 wherein the metal traces have temple gate paths.

11. The apparatus defined in claim 4 wherein the metal traces have zigzag paths.

12. The apparatus defined in claim 4 wherein the holes are circular.

13. The apparatus defined in claim 4 wherein the holes are formed from slits in the flexible substrate layer.

14. The apparatus defined in claim 4 wherein the holes are slots.

15. The apparatus defined in claim 4 wherein the holes have straight and curved edges.

16. Apparatus, comprising:
a flexible substrate layer having holes and a bend; and
conductive traces on the flexible substrate, wherein the holes are formed between the conductive traces and wherein the flexible substrate has a portion that twists to form a three-dimensional shape overlapping the bend.

17. The apparatus defined in claim 16 further comprising an array of light-emitting pixels on the flexible substrate in a portion of the flexible substrate that does not overlap the bend.

18. The apparatus defined in claim 17 wherein the conductive traces comprise meandering metal traces that overlap the bend.

19. The apparatus defined in claim 18 wherein the holes comprise an array of through holes and wherein the metal traces run along portions of the flexible printed circuit between the holes.

20. A method, comprising:
forming a flexible polymer substrate that has an array of openings and meandering conductive traces between the openings;
bending the flexible polymer substrate to form a bend, wherein bending the flexible polymer substrate cause the flexible polymer substrate to twist and form a three-dimensional shape overlapping the bend.

21. The method defined in claim 20 further comprising:
forming a protective polymer coating on the flexible polymer substrate overlapping the bend.

22. The method defined in claim 21 wherein forming the protective polymer coating comprises:
applying a liquid polymer precursor to the flexible polymer substrate after bending the flexible polymer substrate; and
curing the liquid polymer precursor to form the protective polymer coating.

23. The method defined in claim 21 wherein forming the protective polymer coating comprises:
stretching the flexible polymer substrate before bending the flexible polymer substrate;
applying a liquid polymer precursor to the stretched flexible polymer substrate before bending the flexible polymer substrate; and
curing the liquid polymer precursor to form the protective polymer coating before bending the flexible polymer substrate.

24. The method defined in claim 21 wherein forming the protective polymer coating comprises:
applying a liquid polymer precursor to the flexible polymer substrate before bending the flexible polymer substrate; and
curing the liquid polymer precursor to form the protective polymer coating after bending the flexible polymer substrate.
